(19) United States
(12) Patent Application Publication
(10) Pub. No.: US 2018/0372785 A1
(43) Pub. Date: Dec. 27, 2018

(54) CABLE SCAN TESTER

(71) Applicant: Bentek Corporation, San Jose, CA (US)

(72) Inventor: Ed Shallo, San Jose, CA (US)

(21) Appl. No.: 15/628,929

(22) Filed: Jun. 21, 2017

(51) Int. Cl. G01R 31/02

(52) U.S. Cl. CPC G01R 31/021; G01R 31/024

(57) ABSTRACT

A scan apparatus includes a scan controller configured to control a scan of a cable harness using fixtures coupled to the scan apparatus and having connectors to communicably connect to respective ends of a cable harness under test. The fixtures may act as adapters for cable harnesses whose cable connectors are compatible with the connectors of the fixtures without regard to connector compatibility with the scan apparatus or its dedicated cables that connect the scan apparatus to the fixtures. To scan cable harnesses having connectors incompatible with current fixtures, the current fixtures may be swapped out for fixtures having connectors that are compatible with the connectors of the cable harnesses to be scanned.

### BACKGROUND

Power systems frequently generate and distribute power in the form of electricity from one or more power sources to end users, sometimes via a power distribution grid. For example, fossil fuel or nuclear power sources may generate and deliver electrical power to a distribution system, which distributes electricity via power lines constituting a grid to, e.g., residential or commercial end users. Solar power may be used similarly to generate and distribute electricity. Solar-sourced electricity commonly supplements fossil fuel- or nuclear power-sourced electricity, although in some applications solar power may be the sole source of electricity at the end user.

A power system can be said to include a power generator and a “balance of system” (BOS) comprising all components used to modify, distribute, and ultimately deliver electricity generated from the energy source to the end user. For example, in a fossil-fuel- or nuclear-sourced power system, the BOS includes such components as power lines and other cabling, insulators, connectors, etc. In a solar or photovoltaic (PV) power system, the BOS includes such components as cabling, switches, enclosures, inverters, etc.

There are a variety of industrial and commercial equipment that require the use of cables to transmit electricity, data and other information. To fit the particular application, these cables may be measured and cut to specified lengths, labeled, bundled together as groups of cables, per specifications, have connectors applied, and be packaged, often in a circular form, either on a spool or in other packaging. The finished product is commonly called a cable harness.

A cable harness should have no compromising or disabling faults, but quality control in manufacturing can be imperfect and a solution that avoids installation of a faulty cable harness is needed. Attempts at visual examination, including examination of cable insulation and connectors, enjoy some success but cannot, for example, detect unseen faults resulting from flaws in, for example, conductive material, insulation, connectors, and termination.

Furthermore, it may be desirable to scan cables of a cable harness for characteristics of the cables other than inherent faults, such as electrical resistance, capacitance, and connector integrity. Attempts at scanning cables, however, scan cables one-at-a-time, which is cumbersome and time-consuming. Embodiments disclosed herein enable scanning of cables and/or a cable harness to be performed with greater ease and efficiency.

### SUMMARY

In a first aspect, a scan apparatus comprises circuitry including a scan controller configured to control a scan of a cable harness; first and second cabling units each having one or more connectors by which the scan controller is configured to be operably coupled to the first and second cabling units to control the scan via the first cabling unit and receive an output of the scan via the second cabling unit; and an interface configured for communication of at least one of a scan result derived from the received output and a scan request input to the scan apparatus.

In a second aspect, a scan system comprises a scan apparatus including circuitry including a scan controller configured to control a scan of a cable harness; first and second cabling units each having one or more connectors by which the scan controller is configured to be operably coupled to the first and second cabling units to control the scan via the first cabling unit and receive an output of the scan via the second cabling unit; and an interface configured for communication of at least one of a scan result derived from the received output and a scan request input to the scan apparatus; a first fixture having a first connector configured to be communicably coupled to and uncoupled from the scan apparatus via the first cabling unit, and a second connector configured to be communicably coupled to and uncoupled from a first end of a cable harness; and a second fixture having a third connector configured to be communicably coupled to and uncoupled from the scan apparatus via the second cabling unit, and a fourth connector configure to be communicably coupled to and uncoupled from a second end of the cable harness.

In a third aspect, a method of scanning a plurality of cable harnesses comprises configuring a scanning apparatus having first and second cabling units to control scanning of first and second cable harnesses each having first and second ends; communicably connecting a first fixture to the first cabling unit and a second fixture to the second cabling unit; communicably connecting the first end of the first cable harness to the first fixture via respective mutually compatible first connectors; communicably connecting the second end of the first cable harness to the second fixture via respective mutually compatible second connectors; scanning the first cable harness with a first scan signal provided by the scan apparatus through the first cabling unit, the first fixture, the first cable harness, the second fixture, and the second cabling unit; disconnecting the first fixture from the first cabling unit and the second fixture from the second cabling unit; communicably connecting a third fixture to the first cabling unit and a fourth fixture to the second cabling unit; communicably connecting the first end of the second cable harness to the third fixture via respective mutually compatible third connectors; communicably connecting the second end of the second cable harness to the fourth fixture via respective mutually compatible fourth connectors; and scanning the second cable harness with a second scan signal provided by the scan apparatus through the first cabling unit, the third fixture, the second cable harness, the fourth fixture, and the second cabling unit; wherein the first connectors of the first cable harness are incompatible with the third connectors of the third fixture.

### BRIEF DESCRIPTION OF THE DRAWINGS

The accompanying drawings are considered illustrative of inventive concepts described throughout the disclosure. To the extent that the drawings show inventive concepts, possibly including analysis that is properly considered to be inventive activity, the drawings nevertheless are illustrative in nature and should not be considered unduly limitative in any way.

FIG. 1 illustrates an example of a solar power system.

FIG. 2 illustrates an example of a cable harness as an example of a subject for testing.

FIG. 3 illustrates an example of a combiner.

FIG. 4 illustrates an example of a scanner configured to scan cables or a cable harness.

FIG. 5 illustrates an example of a test setup that includes a scanner configured to scan cables or a cable harness.

### DETAILED DESCRIPTION

Embodiments are described herein that, for example, enable scanning of cables or a cable harness in an easier and more consistent and efficient manner than known methods, and may have notable applicability to BOS components in power distribution systems of which solar power systems are an example. Other improvements and advantages also flow from the various embodiments, whether or not specifically disclosed. All such improvements and advantages are proper considered within the spirit and scope of the disclosed embodiments, without limitation.

Throughout the description, reference may be made to “electricity”, “current”, “electrical current”, “power”, “electrical power”, or the like. Although each of these terms may be differentiable by one of ordinary skill in the art, especially in context, one or more of these terms may be substituted for or used in combination with another herein for convenience, without limitation in terms of scope.

In a similar way, reference may be made to “test” or “scan”; “connected” or “coupled”; and “processor”, “processing device”, or “computing device”, for example, and one or more of these terms may be substituted for or used in combination with another herein for convenience without limitation in terms of scope. In addition, the singular (e.g., “processor”) may describe the plural (“processors”) in addition or alternatively as appropriate and understood by the person of ordinary skill in the art.

Therefore, a solar power system is described as a representative context for scanners and scanner assemblies according to various embodiments. Although a solar power system is illustrated, one of ordinary skill in the art will readily understand that other power systems utilizing similar components may have similar issues addressable by the presently disclosed embodiments. For example, electrical power generated from a fossil fuel or nuclear energy may be distributed using cables or cable harnesses which would also benefit from a more efficient way to scan them for faults.

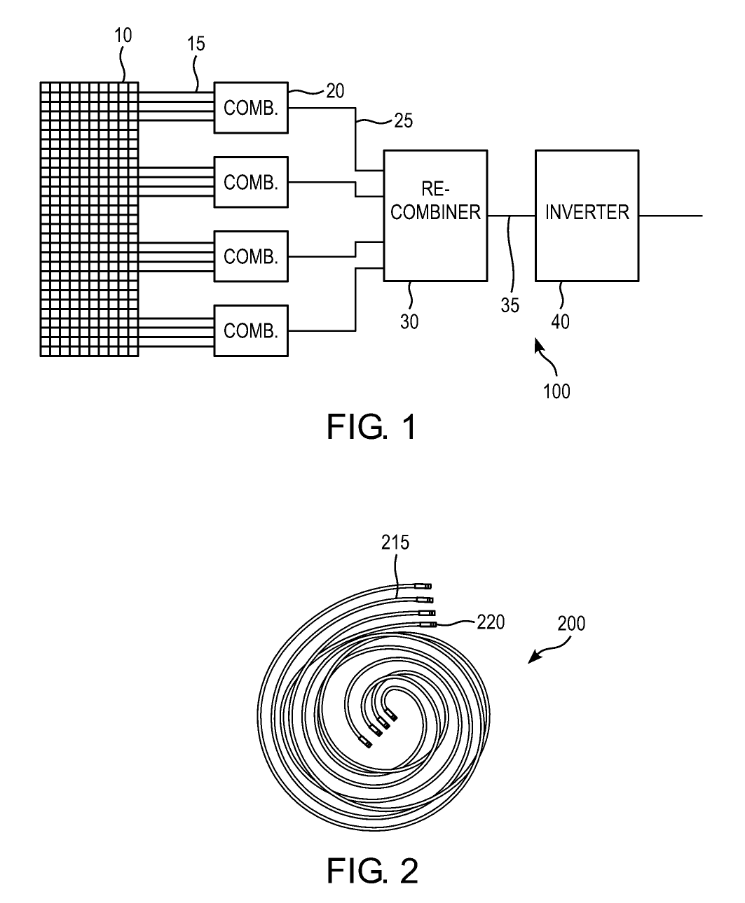

FIG. 1 illustrates an example of a solar power system 100. Solar power system 100 may include, for example, a PV panel array 10 configured of a plurality of “strings” each comprising one or more series-connected PV panels. PV panels are sometimes referred to as PV modules, solar panels, or solar modules, to name three examples. The PV panel or panels in each string may generate direct current from sunlight by the photovoltaic effect. At least some strings may be arranged in electrical parallel. Each string may output direct current power from the last PV panel in the series via one or more cables 15, which provide the direct current as an input to a combiner 20. In accordance with the parallel arrangement of cables 15, the direct current inputs to each combiner 20 may be parallel inputs. In each combiner 20 shown in the present illustration, the direct current inputs may be combined into one output which is transmitted to a recombiner 30 via a cable 25. Recombiner 30 may provide direct current output to an inverter 40 via a cable 35 in the illustration shown. The output of inverter 40 may be provided to a load or to a power grid, for example.

FIG. 1 illustrates four combiners 20, each of which may receive power over four cables 15 from PV panel array 10 and deliver power to recombiner 30, but one of ordinary skill in the art will readily understand that the depicted system is merely illustrative and more or fewer PV panel arrays 10, cables 15, combiners 20, and/or recombiners 30 (and/or one or more re-recombiners (not shown) if desired) may be employed based on considerations such as power requirements, capacity, ability to scale, cost, convenience, etc.

In some embodiments, the inputs to combiners 20 may be direct current (DC), single-phase alternating current (AC), or three-phase AC (summed, with optional neutral) inputs via corresponding cables 15, and combined into one or more direct current outputs via cables 25.

FIG. 2 illustrates one nonlimiting example of a cable harness 200 comprising a plurality of cables 215 in accordance with embodiments disclosed herein. Cable harness 200 may be generally useful in any power distribution system. As illustrated, and without limitation, cable harness 200 (particularly, cables 215) may be constructed and/or assembled for deployment in solar power system 100 as cables 15, for example, although other cables (including cables 25 and 35) may be assembled as cable harness 200. Cables 215 may comprise distinct insulated conductors (positive or negative) or combined positive/negative conductors; three-phase conductors, or ground conductors. One or more ends of cables 215 may be terminated with suitable connectors 220, examples of which may include MC3, MC4, and Tyco Solarlok® connectors, although no limitation on the number or type of connector is intended.

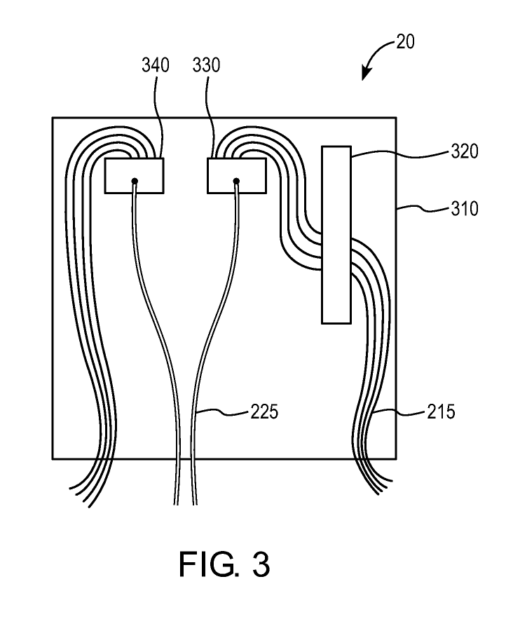

FIG. 3 illustrates an example of combiner 20 suitable for use in solar power system 100. As shown in FIG. 3, combiner 20 may comprise an enclosure 310, one or more fuses 320, a positive busbar or block 330, and a negative busbar or block 340. configured as shown to receive four input cables 215 and combine their inputs to a common output cable 225. Combiner 20 may house a variety of other components such as, for example, a DC disconnect, surge protection components, rapid-disconnect contacts, cable whips, and/or pre-wiring, as well as current monitoring, arc-fault, and other sensors. Enclosure 310 may be constructed primarily from aluminum, steel, fiberglass, and/or polycarbonate, although other materials may be used additionally or alternatively.

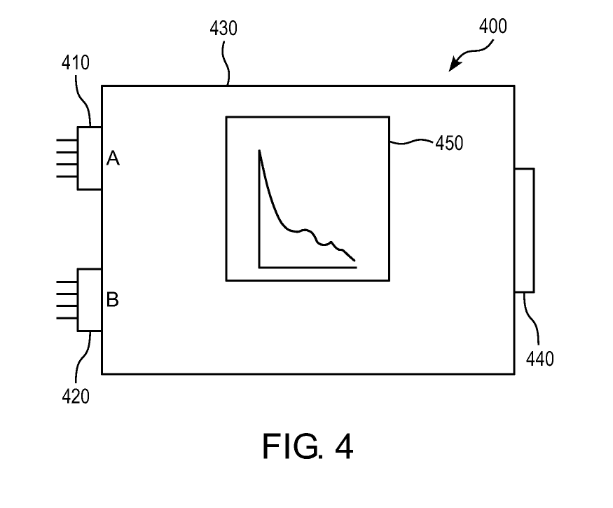

FIG. 4 illustrates an example of a scanner 400 configured, e.g., to scan cables or a cable harness for faults or other characteristics according to one or more embodiments disclosed herein. The illustrated scanner 400 may include a connector 410 and a connector 420 removably attached to a scanner box 430 as shown; however, any number of connectors may be provided. In the illustrated example, connector 410 and connector 420 may be removably connected to respective ends of cable harness 200 as described below.

In one or more embodiments, scanner 400 may be configured with a scan controller and other suitable hardware and/or software to scan one or more cables 215 of cable harness 200 for any of a variety of characteristics, of which faults related to (dis)continuity, resistance, capacitance, connector polarity, and connector integrity are nonlimiting examples. To this end, scanner 400 may also include a test component comprising hardware and/or software to analyze results of the scan, determine one or more characteristics of the cables or cable harness from the analyzed output, and derive scan results from the one or more characteristics. Alternatively or in addition, some or all of the hardware/software, including a scan controller or test component, may be provided separately from scanner 400 and/or externally of scanner box 430.

One of ordinary skill in the art will readily understand and be able to scan, test, and devise tests for other conditions or characteristics, including conditions or characteristics other than faults and faults other than those mentioned.

Scanner 400 may further include an interface 440 configured to communicate via wires or wirelessly with a computing device such as, by way of nonlimiting example, a personal computer, laptop, tablet, smartphone, etc. using appropriate software and/or hardware. In combination with applications that may be provided for the computing device and/or scanner 400, scanner 400 may be controlled to scan cable harness 200 via the respective fixtures and/or provide results of the scan.

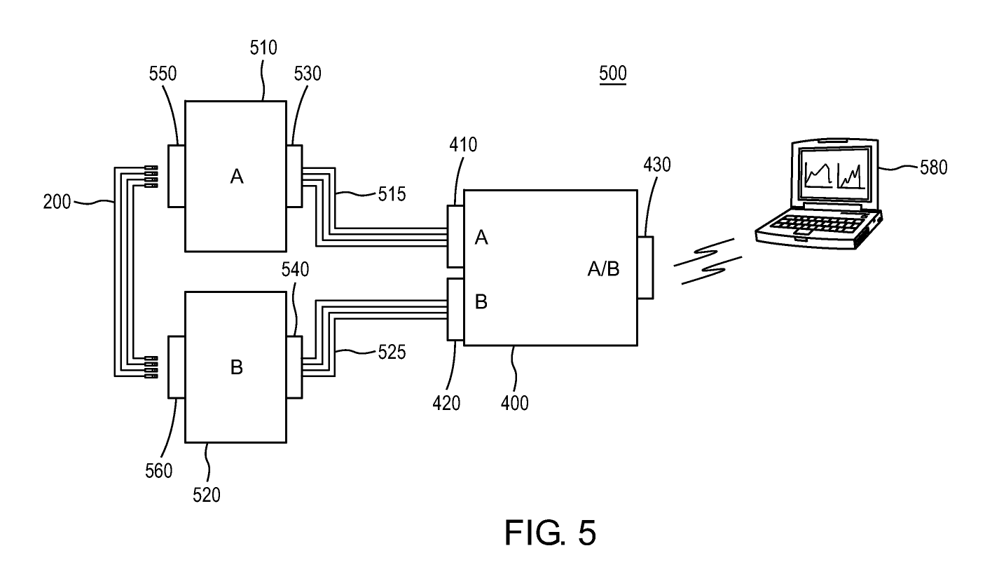

FIG. 5 illustrates an example of a test setup 500 for scanning cable harness 200 in accordance with one or more embodiments described herein. Test setup 500, as illustrated, may include a fixture 510, a fixture 520, and scanner 400. Scanner 400 may include some or all of the features described above with respect to the scanner shown in FIG. 4 with additional features and modifications as needed or deemed appropriate by the person of ordinary skill in the art. Thus, for example, connector 410 of scanner 400 may be electrically, optically, or otherwise communicably coupled to fixture 510 at a connector 530 by, e.g., one or more electrical or optical cables 515 and connector 420 of scanner 400 may be electrically, optically, or otherwise communicably coupled to fixture 520 at a connector 540 by, e.g., one or more electrical or optical cables 525. Fixture 510 and fixture 520 may have additional connectors 550 and 560, respectively, for electrically or otherwise coupling with connectors 220 of cables 215 that comprise cable harness 200. Fixtures 510 and 520 may have, in their interior or otherwise, cables (not shown) coupling connectors 530, 540 with connectors 550, 560 (i.e., coupling cables 515, 525 with the respective ends of cable harness 200).

In accordance with features of test setup 500, cable harness 200 may be scanned for faults, indicators of faults, and/or other considerations of interest, for example. Scanner 400 may be designed with components that are chosen in accordance with the desired testing. Of note is the ease and efficiency of scanning cables 215 using test setup 500. For example, by simply connecting the ends of cables 215 to connectors 550 and 560 of fixtures 510 and 520, respectively, one or more of cables 215, or even the entire cable harness 200, can be tested by scanner 400, in contrast to the individual cable-by-cable connecting, testing, and disconnecting of the related art.

In some embodiments, cables 515 and 525 may be dedicated to scanner 400 and fixtures 510, 520 may be similar to an adapter providing a custom interface for cables 215 or cable harness 200 to communicate with scanner 400. Thus, regardless of the form of connection between scanner 400 and cables 515, 525 or between cables 515, 525 and fixtures 510, 520, one cable harness after another may be connected to fixtures 510, 520 so long as the connectors at the ends of cable harness 200 are compatible with connectors 550, 560. If a cable harness having incompatible connectors is to be scanned, another set of fixtures configured for coupling to scanner 400 via cables 515, 525 and having connectors 550, 560 compatible with the cable harness may be swapped in for fixtures 510, 520 for scanning the new cable harness. In this manner, substituting the fixtures may be sufficient to scan a variety of cable harnesses without requiring individual adapters for each cable end or substitution of cables 515, 525.

In these and other embodiments, test setup 500 may be portable and easily transported to any of a variety of sites to test cable harnesses 200. Additionally or alternatively, test setup 500 may be arranged at a single location and cable harnesses brought to the test setup for testing. For example, test setup 500 may be located where cable harnesses are conveyed in volume, such as following their assembly, with each cable harness in turn being connected to connectors 550, 560, tested, and disconnected for the next cable harness to be connected and tested. Similarly, multiple unharnessed cables may be connected and scanned simultaneously or substantially so. Additionally or alternatively, test setup 500 may be transported to a remote site such as a panel, combiner, or other installation site, at which site cables or a cable harness can be scanned as described herein.

Results of a scan may be shown via an optional display 440 illustrated with scanner box 430. For example, a graphical representation of scan results (characteristics of the cables or cable harness) may be displayed. In some embodiments, a simple light indicator of a fault (or no-fault) condition or other characteristic may be provided in the display or separately. Other result indicators will become readily apparent to one of ordinary skill in the art.

Although embodiments are described in which cables 215 may be electrical solar power cables, one or ordinary skill in the art will readily recognize that optical cables or other cables may be tested in a similar manner with appropriate modifications to fixtures 510, 520 and/or hardware, software, or other components of scanner 400 or the system described above. Such modifications are considered within the spirit and scope of the disclosure.

Alternatively or additionally, scan results may be communicated via wires or wirelessly to a local or remote computing device such as a personal computer, laptop, tablet, smartphone, etc. using appropriate software and/or hardware. FIG. 5 shows an example of a wireless communication to a laptop 580. In some embodiments, the local or remote computing device may receive the scan results and add them to a database. For example, results of scanning multiple cable harnesses may be retrievably stored in the database referenced to the cable harnesses, respectively, by appropriate identifiers.

One or more features and operations described herein, including but not limited to the scanning and testing operations, may be implemented using any suitable controller(s) or processor(s) and software application(s) which may be stored on any suitable storage location or computer-readable medium. One or more software applications may provide instructions that enable one or more processors or controllers to perform the operations described herein. The software application or applications may be embodied as instructions in a computer-readable medium for use by or in connection with a computer or any instruction execution system. For the purposes of this description, a computer-readable medium can be any apparatus that can contain, store, communicate, propagate, or transport the program instructions for use by or in connection with the instruction execution system, apparatus, or device.

The computer-readable medium may be a non-transitory electronic, magnetic, optical, electromagnetic, infrared, semiconductor system (or apparatus or device), or propagation medium. Examples of a computer-readable medium include a semiconductor or solid state memory, magnetic tape, a removable computer diskette, a random access memory (RAM), a read-only memory (ROM), a rigid magnetic disk, and an optical disk. Current examples of optical disks include DVD, compact disk-read-only memory (CD-ROM), and compact disk-read/write (CD-R/W).

Although various features, advantages, and improvements have been described in accordance with the embodiments shown, one of ordinary skill in the art will readily recognize variations and modifications to the embodiments as disclosed. All such variations and modifications that basically rely on the inventive concepts by which the art has been advanced are properly considered within the spirit and scope of the invention.

What is claimed is:

1. A scan apparatus, comprising:
circuitry including a scan controller configured to control a scan of a cable harness;
first and second cabling units each having one or more connectors by which the scan controller is configured to be operably coupled to the first and second cabling units to control the scan via the first cabling unit and receive an output of the scan via the second cabling unit; and
an interface configured for communication of at least one of a scan result derived from the received output and a scan request input to the scan apparatus.

2. The scan apparatus of claim 1, wherein the circuitry includes a test component configured with a processor to analyze the received output, determine one or more characteristics of the cable harness from the analyzed output, and derive the output scan result from the one or more characteristics.

3. The scan apparatus of claim 2,
wherein the cable harness comprises a plurality of cables; and
wherein the one or more characteristics include continuity status of at least one of the cables in the cable harness.

4. The scan apparatus of claim 2, further comprising:
a display;
wherein the processor is configured to provide result data of scanning the cable harness formatted for output by the display.

5. The scan apparatus of claim 4, wherein the display includes an illumination source configured to output a light indicator of a fault in the cable harness in accordance with the result data.

6. The scan apparatus of claim 4, wherein the display includes an illumination source configured to output a light indicator of no fault in the cable harness in accordance with the result data.

7. The scan apparatus of claim 1, wherein the scan controller is configured to be operably connected to the first and second cabling units to control the scan via the first cabling unit in accordance with one or more signals received via the second cabling unit.

8. A scan system, comprising:
a scan apparatus including:
circuitry including a scan controller configured to control a scan of a cable harness;
first and second cabling units each having one or more connectors by which the scan controller is configured to be operably coupled to the first and second cabling units to control the scan via the first cabling unit and receive an output of the scan via the second cabling unit; and
an interface configured for communication of at least one of a scan result derived from the received output and a scan request input to the scan apparatus;
a first fixture having a first connector configured to be communicably coupled to and uncoupled from the scan apparatus via the first cabling unit, and a second connector configured to be communicably coupled to and uncoupled from a first end of a cable harness; and
a second fixture having a third connector configured to be communicably coupled to and uncoupled from the scan apparatus via the second cabling unit, and a fourth connector configure to be communicably coupled to and uncoupled from a second end of the cable harness.

9. The scan system of claim 8, wherein the circuitry includes a test component configured with a processor to analyze the received output, determine one or more characteristics of the cable harness from the analyzed output, and derive the output scan result from the one or more characteristics.

10. The scan system of claim 9,
wherein the cable harness comprises a plurality of cables; and
wherein the one or more characteristics include continuity status of at least one of the cables in the cable harness.

11. The scan system of claim 9, further comprising:
a display;
wherein the processor is configured to provide result data of scanning the cable harness formatted for output by the display.

12. The scan system of claim 11, wherein the display includes an illumination source configured to output a light indicator of a fault in the cable harness in accordance with the result data.

13. The scan system of claim 11, wherein the display includes an illumination source configured to output a light indicator of no fault in the cable harness in accordance with the result data.

14. The scan system of claim 8, wherein the scan controller is operably connected to the first and second cabling units to control the scan via the first cabling unit in accordance with one or more signals received via the second cabling unit.

15. A method of scanning a plurality of cable harnesses, comprising:
configuring a scanning apparatus having first and second cabling units to control scanning of first and second cable harnesses each having first and second ends;
communicably connecting a first fixture to the first cabling unit and a second fixture to the second cabling unit;
communicably connecting the first end of the first cable harness to the first fixture via respective mutually compatible first connectors;
communicably connecting the second end of the first cable harness to the second fixture via respective mutually compatible second connectors;
scanning the first cable harness with a first scan signal provided by the scan apparatus through the first cabling unit, the first fixture, the first cable harness, the second fixture, and the second cabling unit;
disconnecting the first fixture from the first cabling unit and the second fixture from the second cabling unit;
communicably connecting a third fixture to the first cabling unit and a fourth fixture to the second cabling unit;
communicably connecting the first end of the second cable harness to the third fixture via respective mutually compatible third connectors;
communicably connecting the second end of the second cable harness to the fourth fixture via respective mutually compatible fourth connectors; and
scanning the second cable harness with a second scan signal provided by the scan apparatus through the first cabling unit, the third fixture, the second cable harness, the fourth fixture, and the second cabling unit;
wherein the first connectors of the first cable harness are incompatible with the third connectors of the third fixture.

16. The method of claim 15, wherein the second connectors of the first cable harness are incompatible with the fourth connectors of the fourth fixture.

17. The method of claim 15, further comprising wirelessly transmitting results of scanning the first and second cable harnesses.

18. The method of claim 15, further comprising displaying results of scanning the first and second cable harnesses.

19. The method of claim 15, further comprising audibly providing results of scanning the first and second cable harnesses.

20. The method of claim 15, further comprising adding results of scanning the first and second cable harnesses to a database configured to retrievably store the results referenced to the first and second cable harnesses, respectively.
